(19) United States
(12) Patent Application Publication
(10) Pub. No.: US 2024/0321627 A1
(43) Pub. Date: Sep. 26, 2024

(54) METHOD FOR PRODUCING AN ELECTRONIC SEMICONDUCTOR COMPONENT

(71) Applicant: MI2-FACTORY GMBH, Jena (DE)

(72) Inventors: Constantin CSATO, Stammbach (DE); Florian KRIPPENDORF, Jena (DE)

(21) Appl. No.: 18/578,143

(22) PCT Filed: Jul. 12, 2022
(86) PCT No.: PCT/EP2022/069462

§ 371 Date: Jan. 10, 2024

(30) Foreign Application Priority Data
Jul. 15, 2021 (DE) 10 2021 118 315.4

(51) Int. Cl. H01L 21/762

(52) U.S. Cl. CPC H01L 21/76254

(57) ABSTRACT

A method for producing an electronic semiconductor component includes doping a first layer made of SiC in a donor substrate by ion implantation, creating a predetermined breaking site in the donor substrate, and producing a connection between donor substrate and acceptor substrate, wherein the first layer is arranged in an area between the acceptor substrate and a remaining part of the donor substrate. Finally, the donor substrate is split in the area of the predetermined breaking site to create the pretreated composite substrate, wherein the pretreated composite substrate has the acceptor substrate and a doped layer connected thereto, which includes at least one section of the first layer of the donor substrate. In addition, implantation defects are healed by laser irradiation during the process.

### CROSS-REFERENCE TO RELATED APPLICATIONS

The present application is a 371 of International application PCT/EP2022/069462, filed Jul. 12, 2022, which claims priority of DE 10 2021 118 315.4, filed Jul. 15, 2021, the priority of these applications is hereby claimed and these applications are incorporated herein by reference.

### BACKGROUND OF THE INVENTION

The invention relates to a method for producing an electronic semiconductor component.

Discrete high-blocking power semiconductor components having more than 600 V nominal blocking voltage are generally vertically constructed both in silicon and in SiC. For diodes, e.g., MPS (merged-pin Schottky) diodes, Schottky diodes, or p-n diodes, this means that the cathode is arranged on the substrate front side and the anode is arranged on the substrate rear side. A similar arrangement applies in the case of vertical power MOS (metal-oxide-semiconductor) components. Gate and source electrode are located on the substrate front side, the drain electrode on the substrate rear side. The actual transistor element and/or the channel area can be arranged in conventional power MOSFETs parallel to the surface (D-MOS) or perpendicular to the surface (Trench-MOS). Special designs have become established for SiC MOSFETs, such as trench transistors.

Depending on the required blocking capability (reverse blocking voltage), the width of the drift zone (=active zone, voltage-absorbing layer) is set. For example, the width of the drift zone for a 600 V MOSFET component in silicon will be approximately 50 μm.

In so-called superjunction components, the width of the voltage-absorbing layer can be somewhat reduced in relation to “simple” vertical MOSFETs. The special feature of this type of vertical components is that the drift is characterized by alternately arranged vertical p-doped and n-doped columns. The additionally introduced p-doping compensates in the case of blocking for the increased charge in the n-doped area, which determines the resistance between source electrode and drain electrode in the switched-on state. Therefore, with equal blocking capability, the on-state resistance can be reduced by approximately up to a factor of 10 in relation to conventional vertical MOS transistors. The actual transistor element, or the channel area, can be arranged in superjunction MOSFET architectures parallel to the surface (D-MOS) or perpendicular to the surface (trench-MOS).

The special material properties of SiC require the provision of specific production methods and the application of specific architectures of the channel and transistor areas for vertical power semiconductor components.

The active zones of all vertical power diodes or all power transistors (MOSFET and J-FET) are usually formed in monocrystalline epitaxial layers. These epitaxial layers are built up or deposited on crystalline carrier wafers. The doping and vertical extension (thickness) of the active epitaxial zone can thus be matched to the respective blocking voltage and the highly-doped carrier wafer can be optimized with respect to its doping so that its contribution to the on-state resistance is minimized.

In particular with SiC substrates, the above-described production of the layer structure is complex and costly, since the epitaxial layer deposition and also the provision of monocrystalline carrier wafers is enormously cost-intensive.

DE 10 2019 112 985 A1 alternatively proposes producing the semiconductor component without epitaxial deposition by splitting off a substrate from an SiC wafer and subsequently ion implanting the drift zone using an energy filter.

### SUMMARY OF THE INVENTION

It is an object of the present invention to provide a method for producing an electronic semiconductor component which is associated with reduced complexity and lower costs.

According to a first aspect of the invention, a method for producing an electronic semiconductor component (50) via the intermediate step of creating a pretreated composite substrate (18), wherein the pretreated composite substrate (18) comprises an acceptor substrate (28) and a first section (48) of a donor substrate (12), which comprises at least one doped layer (32), comprises the steps of:
a) providing the donor substrate, which comprises monocrystalline SiC;
b) doping a complete first layer in the donor substrate by ion implantation, wherein during the doping a predetermined dopant depth profile is created in the first layer of the donor substrate, wherein the first layer extends from an outer face of the donor substrate facing toward the ion beam to a predetermined doping depth, where a remaining part of the donor substrate adjoins, and wherein implantation defects are created during the doping;
c) creating a predetermined breaking site in the donor substrate extending substantially parallel to the outer face of the donor substrate;
d) providing the acceptor substrate and producing a bonded connection between donor substrate and acceptor substrate, wherein the first layer is arranged in an area between the acceptor substrate and the remaining part of the donor substrate;
e) splitting the donor substrate in the area of the predetermined breaking site to create the pretreated composite substrate, wherein the pretreated composite substrate comprises the acceptor substrate and the first section of the donor substrate connected thereto, which first section has at least one doped layer, wherein the doped layer comprises at least one section of the first layer of the donor substrate, wherein the splitting takes place such that the first section of the donor substrate has a first surface in the area of the predetermined breaking site, which first surface faces away from the acceptor substrate in the composite substrate,
f) introducing at least one further, preferably a plurality of further structural elements of the semiconductor component (50) into the composite substrate (18) from the first surface (58) and/or arranging at least one further, preferably a plurality of further structural elements of the semiconductor component (50) on the first surface (58),
   wherein after at least one of steps b), c), e), and f), among these preferably after step e) and/or after or during step f), a healing step is carried out for the implantation defects in the first layer (21) of the donor substrate (12) and/or in the first section (48) of the donor substrate (26) by laser irradiation (43).

A healing step by laser irradiation is preferably carried out after step e) and/or after or during step f). In this case, it is possible to use an acceptor substrate which does not have to be high-temperature proof, for example made of silicon. During step f) means that certain structural elements of the semiconductor component, for the production of which ion implantation is not required, can also be created or applied after the healing.

The healing step by laser irradiation after step e) and/or after or during step f) is preferably carried out on the first surface of the composite substrate.

During the healing step by laser irradiation after step e) and/or after or during step f), the temperature in the area of the acceptor substrate preferably does not exceed 1500° C., more preferably 1450° C., still more preferably 1400° C., particularly preferably 1350° C.

During the healing step by laser irradiation after step e) and/or after or during step f), a temperature gradient is preferably formed in the composite substrate, wherein the temperature close to the first surface is higher than in the acceptor substrate.

The temperature in the doped layer during the healing step by laser irradiation after step e) and/or after or during step f) is at least temporarily preferably at least 1400° C., more preferably at least 1450° C., particularly preferably at least 1500° C.

In one embodiment, the predetermined breaking site is in the area of the remaining part of the donor substrate, and, in addition, after step e), before the healing step, the further step is carried out of carrying out an ion implantation, preferably using an energy filter, in the composite substrate from the first surface, by which a supplementary doped layer is formed.

The ion implantation in the composite substrate preferably extends here at least to the doped layer.

The ion implantation in the composite substrate is preferably carried out such that a doping concentration in the supplementary doped layer is higher than in an area of the doped layer facing toward the supplementary doped layer, preferably higher by a factor of 1.5 to 100, particularly preferably by a factor of 2 to 10.

The temperature in the supplementary doped layer during the healing step by laser irradiation after step e) and/or after or during step f) is at least temporarily preferably at least 1400° C., more preferably at least 1450° C., particularly preferably at least 1500° C.

Alternatively or additionally, a healing step by laser irradiation can be carried out after at least one of steps b) and c).

The healing step by laser irradiation after at least one of steps b) and c) is preferably carried out on the outer face of the donor substrate.

During the healing step by laser irradiation after at least one of steps b) and c), the temperature in the area of the remaining part of the donor substrate preferably does not exceed 1500° C., more preferably 1450° C., still more preferably 1400° C., particularly preferably 1350° C.

During the healing step by laser irradiation after at least one of steps b) and c), a temperature gradient is preferably formed in the donor substrate, wherein the temperature is higher in the first layer than in the remaining part of the donor substrate.

The temperature in the first layer during the healing step by laser irradiation after at least one of steps b) and c) is at least temporarily preferably at least 1400° C., more preferably at least 1450° C., particularly preferably at least 1500° C.

A healing step is preferably generally carried out by pulsed light introduction, wherein preferably a large number of individual pulses are deposited per irradiation point, particularly preferably between 100 and 5000 individual pulses.

In general, it is also preferred that, during a healing step, the temperature introduction in the depth and/or the temperature gradient is controlled by sequential or simultaneous application of light of different wavelengths, pulse durations, and/or pulse numbers.

It is also preferred that the pulse frequency is in the range of 20 Hz to 3 kHz, more preferably between 30 Hz and 1 kHz.

In one preferred embodiment, the pulse width is in the range of 1 to 1000 ns.

The wavelength of the light is preferably in the range between 250 and 400 nm.

Very generally, in the scope of the invention a healing step can take place immediately after each completed ion implantation, or the implantation defects of multiple successive ion implantations are healed simultaneously in one healing step. In the donor substrate, the healing can also take place by way of equilibrium processes (for example in the furnace), in which the entire donor substrate is heated to a temperature of greater than 1400° C. or greater than 1450° C. or greater than 1500° C.

Overall, a single healing step according to the invention by laser irradiation can thus be provided (applied either to the donor substrate or to the composite substrate), two healing steps according to the invention by laser irradiation can be provided (applied to the donor substrate and to the composite substrate or in each case to only one of the two), or three or more healing steps according to the invention by laser irradiation can be provided (applied to the donor substrate and to the composite substrate or in each case to only one of the two).

If the healing step according to the invention is applied to the composite substrate, the composite substrate can already be completely or partially healed or may not yet be healed at all.

The production of source and body areas, channel areas, shielding structures, J-FET structures, connection contacts, edge finishes, etc. can be carried out by ion implantation. The doping can be p-type or n-type, and can be superimposed or introduced in an isolated manner. Suitable masks (lithography) are preferably provided. The implantation steps have typical energies of a few keV up to approximately 1 MeV. The implantation steps are preferably carried out at temperatures between room temperature or 500° C. up to 1000° C. During introduction of the base doping or parts of the base doping after the construction of the composite substrate, the ion energies can reach up to 30 MeV.

The healing of the ion implantation defects, including those defects which are present natively in the composite material upon provision, is performed by laser healing or by light of suitable wavelength and intensity. Suitable wavelengths are those which ensure a sufficient penetration depth and thus energy absorption.

Depending on the depth of the regions to be healed, wavelengths the energy of which is greater than the bandgap (highly absorbing; low depth, i.e., the energy absorption takes place in a small depth range) or is less than the bandgap (large penetration depth, energy absorption takes place in a broad depth range) are used.

The temperature introduction in the depth or the temperature gradient can be controlled by the sequential or simultaneous application of light of different wavelengths, pulse durations, pulse numbers.

The energy introduction can furthermore be controlled by pulse width modulation and modulation of the power density per pulse and by the chronological sequence of pulses, thus, for example, chronological fine structures of rapid double or multiple pulses followed by longer pauses are conceivable, i.e., for example, a pulse width of 50 ns, double pulse in the range of kilohertz, and pause in the range of a few hertz.

Pulse widths are in the range from the picosecond range to the millisecond range, but preferably in the range of 1 to 1000 ns. The pulse frequency is in the range of a few hertz to a few kilohertz, for example, at 50 Hz. A very large parameter space is spanned using the mentioned parameters.

The healing takes place either in the “sub-melt regime”, i.e., in the non-melting regime or in the “full-melt regime”, i.e., in the melting regime.

The irradiation process is preferably carried out in a pulsed manner to prevent excessive heating of the acceptor substrate.

A large number of individual pulses is preferably placed per irradiation point, so that a desired amount of energy per irradiation point is deposited in the material.

Laser healing is preferably a sequential process, for example, pulsed excimer lasers (wavelengths, for example, 308 nm or 355 nm) having pulse lengths in the picosecond range to nanosecond range are used. Typically, each point is occupied, for example, with several hundred or a few thousand laser pulses and the wafer is sequentially scanned.

The laser annealing process is preferably carried out under protective gas atmosphere.

The laser annealing process is preferably carried out after depositing a thin capping layer. The capping layer consists of carbonaceous materials or silicon-containing materials. The capping layer can be chemically or physically modified (melting) during the laser annealing process. The capping layer is removed after the laser annealing step. The capping layer is thin, typically 20 nm to 500 nm.

It is to be noted that further process steps, such as layer depositions, further implantations or etching, etc. can also be between the respective implantation step and the respective healing step. In general, implantation step and healing step do not have to follow one another directly. A single healing step can also heal multiple individual implantations.

The first layer always consists of monocrystalline SiC. Preferably, the donor substrate consists completely of monocrystalline SiC.

The first layer preferably has a thickness of 3 to 15 μm. An ion implantation can be carried out reasonably over a thickness of this order of magnitude.

In one preferred embodiment, the donor substrate is a crystal made of high-quality monocrystalline semi-insulating SiC material having high purity. In particular, this is to be understood as a material in which the concentration of elemental contaminants, in particular N, B, P, is predominantly less than 5E15 cm⁻³. In this context, predominantly means that the criterion applies nearly everywhere in the course of the depth profile, but there can be deviations in certain areas, for example, at the surface. Preferably, this is HT-CVD (high temperature chemical vapor deposition) material in this case.

In one preferred embodiment, the donor substrate is made of SiC of the polytype 4H, 6H, or 3C. These polytypes have proven to be advantageous for the production of semiconductor components.

The outer face of the donor substrate facing toward the ion beam preferably deviates by less than 0.5°, more preferably by less than 0.3°, still more preferably by less than 0.1°, most preferably not at all, from a direction perpendicular to the c direction of the crystal structure of the donor substrate. The advantage in the case of approximately 0° is in particular that the donor substrate can be severed parallel to the outer face and therefore more partial wafers can be obtained from a cylinder.

The donor substrate preferably has a thickness of greater than 100 μm, preferably greater than 200 μm, more preferably greater than 300 μm to 15 cm, preferably up to 10 cm.

In general, it is preferred for the doping of the first layer to supply a p-doping or n-doping having a doping concentration in the first layer of 1E15 cm⁻³ to 5E17 cm⁻³. This doping concentration is very well suitable for the drift zone (active layer, power-absorbing layer) of a large number of high-performance components. The doping can be constant over the thickness of the first layer or can display a doping profile deviating therefrom.

The doping of the first layer is preferably performed using ions of one of the following elements: nitrogen, phosphorus, boron, or aluminum.

The primary energy range of the ion beam during the doping of the first layer is preferably between 1 MeV and 30 MeV, under certain circumstances also up to 50 MeV.

In one preferred embodiment, the doping of the first layer supplies a constant dopant depth profile or a substantially constant dopant depth profile. These are to be understood as profiles having a deviation from a perfectly flat dopant depth profile of less than 20% and preferably less than 10%. In reality, a falling flank adjoins the plateau, i.e., the drop of the profile is not perpendicular or abrupt in the area of the doping depth.

In an alternative embodiment, the doping of the first layer supplies a dopant depth profile falling in steps from the outer face of the donor substrate facing toward the ion beam, wherein the steps are formed in a surface-proximal area of the first layer, facing toward the ion beam, of up to 40%, preferably up to 30% of the total depth of the first layer.

A concentration difference between the highest and the lowest step is preferably at least a factor of 10, preferably at least a factor of 100, more preferably at least a factor of 500, particularly preferably at least a factor of 1000 here.

The depth extension of the flank areas of the steps outweighs the depth extension of the stepped plateau here.

In an alternative embodiment, the doping of the first layer supplies a dopant depth profile falling continuously from the outer face of the donor substrate facing toward the ion beam.

It is preferred here if the continuously falling dopant depth profile is a profile according to the following formula:

$$D ( z ) = {D}_{max} ( 1 - \frac{1}{\sqrt{1 + ∝ ( 1 - \frac{z}{b} )}} ° f ) + {D}_{0}$$

wherein
Dₘₐₓ is the maximum doping concentration,
α is a value between 10 and 10,000,
z is the distance to the outer face,
b is the thickness of the first layer,
f is a tolerance factor between 0.95 and 1.05,
D₀ is the background doping,
   wherein

$${D}_{max} \geq \frac{{ε}_{r} {ε}_{0} {E}_{max}}{2 {e}_{0} {V}_{br}}$$

wherein
Eₘₐₓ is the maximum field,
εᵣ is the relative dielectric constant of the semiconductor,
ε₀ is the dielectric constant in vacuum,
e₀ is the elementary charge of the electron,
V_{br} is the breakdown voltage,
   and wherein

$$b \geq \frac{3 {V}_{br}}{2 {E}_{max}}$$

In general, the further step is preferred of creating a contact layer in a superficial area of the first layer or applying a contact layer to the outer face of the first layer, wherein the production of the bonded connection between donor substrate and acceptor substrate takes place via the contact layer, and wherein the following sequence results: acceptor substrate, contact layer, remaining part of first layer or first layer, remaining part of the donor substrate. A particularly good, low-ohmic connection may thus be ensured between donor substrate and acceptor substrate.

The creation of the contact layer is preferably carried out by ion implantation.

A dopant concentration in the contact layer is preferably at least 100 times, preferably at least 1000 times, more preferably at least 10,000 times, still more preferably at least 100,000 times greater than a mean dopant concentration in the remainder of the first layer or in the first layer. The lowest-ohmic bonded connection possible is thus achieved and a penetration of the field to the interface in the semiconductor component is avoided.

In one preferred embodiment, a dopant concentration in the contact layer is greater than 1E17 cm⁻³, more preferably greater than 1E19 cm⁻³.

The predetermined breaking site is preferably in the area of the first layer, particularly preferably in an end area of the first layer close to the predetermined doping depth, wherein the edge area is particularly preferably not thicker than 1 μm. In this way, as little doped material as possible remains on the donor substrate after the splitting.

In an alternative embodiment, the predetermined breaking site is in the area of the remaining part of the donor substrate, and in addition after step e), the further step is carried out of carrying out an ion implantation in the composite substrate from the side facing away from the acceptor substrate. This has the advantage that an active zone having a greater overall thickness can be formed. Due to the superposition of two different implantations thus made possible, different preferred doping profiles can also be created or preferred doping profiles can be created step-by-step.

In the scope of this alternative embodiment, it is preferred that the ion implantation in the composite substrate supplies a dopant depth profile in a supplementary doped layer, which extends at least up to the doped layer.

The ion implantation in the composite substrate is carried out, for example, such that the combination of both dopant depth profiles of the doped layer and the supplementary doped layer is a constant profile, a profile rising in steps toward the acceptor substrate, or a profile rising continuously toward the acceptor substrate. Other profile shapes are also conceivable.

Diagonally falling flanks in the transition area of the two dopant depth profiles of the doped layer and the supplementary doped layer can overlap here.

An embodiment is particularly preferred in which the doping concentration in the supplementary doped layer is higher than in an area of the doped layer facing toward the supplementary doped layer, preferably higher by a factor of 1.5 to 100, particularly preferably higher by a factor of 2 to 10. The doping concentration in the doped layer can again be a constant profile, a profile rising in steps toward the acceptor substrate, or a profile rising continuously toward the acceptor substrate here.

The creation of the predetermined breaking site is preferably carried out by ion implantation of split-triggering ions.

The split-triggering ions are preferably introduced over the entire width of the donor substrate in order to generate the most uniform separation face possible.

Alternatively, the split-triggering ions can be introduced only over a part of the width of the donor substrate. This reduces the effort during the ion implantation.

The split-triggering ions are preferably only introduced here into an edge area of the donor substrate.

In preferred embodiments, the split-triggering ions are selected from the following: hydrogen (H or H₂), helium (He), boron (B).

It is advantageous in principle if the split-triggering ions are high-energy ions having an energy between 0.5 and 10 MeV, preferably between 0.5 and 5 MeV, more preferably between 0.5 and 2 MeV.

A particle dose of the split-triggering ions is preferably in each case between 1E15 cm⁻² and 5E17 cm⁻². Reliable splitting is achieved with this dose.

The energy sharpness (ΔE/E) of the primary ion beam of the split-triggering ions is preferably less than 10⁻², more preferably less than 10⁻⁴. In this way, it is ensured that the predetermined breaking site has a minimal thickness and the energy loss peak of the ions at the predetermined breaking site is as sharp as possible.

The splitting of the donor substrate is preferably triggered by a temperature treatment of the composite substrate at a temperature of between 600° C. and 1300° C., preferably between 750° C. and 1200° C., more preferably between 850° C. and 1050° C. Alternatively, mechanical methods are also conceivable.

Alternatively, the splitting of the donor substrate can also be carried out by other splitting methods, for example, by laser splitting methods.

In one preferred embodiment, the production of the bonded connection is carried out by a temperature treatment of the composite substrate at a temperature of between 800° C. and 1400° C., preferably between 900° C. and 1300° C.

It is conceivable that to simplify the method both the production of the bonded connection and the splitting of the donor substrate are performed by a temperature treatment, wherein both steps are carried out simultaneously.

Preferably, a pretreatment of at least one, preferably both surfaces to be bonded takes place before the step of producing the bonded connection, in particular a wet chemical treatment, plasma treatment, or ion beam treatment.

The acceptor substrate is preferably temperature stable only up to at most 1400° C., preferably up to at most 1350° C., particularly preferably up to at most 1300° C.

In one preferred embodiment, the acceptor substrate is formed from silicon.

The doping in step b) is preferably carried out using an energy filter, wherein the energy filter is a micro-structured membrane having a predefined structure profile for setting a dopant depth profile, induced by the implantation, in the first layer in the donor substrate. The same applies to all other ion implantations which can take place during the method. Alternative types of ion implantation are, for example, chain implantation or channeling implantation.

Preferably, a posttreatment of the surface of the composite substrate takes place in the area of the predetermined breaking site after the step of splitting, in particular by grinding or polishing and/or the removal of (surface-proximal) defects. Chemical-mechanical polishing is advantageous in particular in this case.

The connection between donor substrate or doped layer and acceptor substrate can be permanent or temporary. In the latter case, the acceptor substrate is removed again after partial or complete processing of the semiconductor component.

According to a further aspect of the invention, a method for producing an electronic semiconductor component comprises the steps of:
providing a pretreated composite substrate, wherein the pretreated composite substrate has an acceptor substrate and at least one completely doped layer made of SiC, which is connected to the acceptor substrate, wherein the doped layer (32) preferably has a thickness of 3 μm to 30 μm;
carrying out a healing step for implantation defects in the doped layer by laser irradiation, wherein the doped layer is substantially completely freed of implantation defects, wherein the temperature in the area of the acceptor substrate does not exceed 1500° C., preferably 1450° C., more preferably 1400° C., particularly preferably 1350° C.

It is initially irrelevant in this case in which way the pretreated composite substrate or the doped layer was created. In addition to the above-described method steps, heterotactic deposition of 3C SiC material on the acceptor substrate also comes into consideration, for example. With respect to that aspect, the fact that the doped SiC layer can be substantially completely freed of defects while the temperature in the more sensitive acceptor substrate is significantly lower is relevant.

The doped layer preferably also in this case has a first surface which faces away from the acceptor substrate, and the laser irradiation takes place on the first surface.

During the healing step by laser irradiation, a temperature gradient is preferably formed in the composite substrate, wherein the temperature close to the first surface is higher than in the acceptor substrate.

The temperature in the doped layer during the healing step by laser irradiation is at least temporarily at least 1400° C., preferably at least 1450° C., particularly preferably at least 1500° C.

Preferred details for the healing step (for example pulsed light introduction, wavelengths, pulse frequency, pulse width, etc.) are identical to those described above.

The acceptor substrate is preferably again only temperature stable up to at most 1400° C., preferably up to at most 1350° C., particularly preferably up to at most 1300° C.

The acceptor substrate is particularly preferably also formed from silicon here.

The electronic semiconductor component is in general preferably a vertical semiconductor component and more preferably a high-blocking vertical power semiconductor component.

Examples of structural elements are: active and passive regions of different doping (source, J-FET p-doped gate structure; MOSFET channel, shielding regions, p-n transitions, resurface edge regions, source-gate contact regions, J-FET channel region), insulation oxides, gate oxides, contact regions (metals, silicides), Schottky electrodes (metals, alloys), ohmic electrodes, source-gate metallization or wiring, passivation layers, trenches for gate electrodes, bond pads, contact holes or contact trenches.

### BRIEF DESCRIPTION OF THE DRAWINGS

FIG. 1 is a schematic cross-sectional view of a first embodiment of the donor substrate which can be used in the method according to the invention.

FIG. 2 is a schematic view of an irradiation arrangement having an energy filter for irradiating the donor substrate.

FIG. 3 is a schematic illustration of the mode of operation of an energy filter which can be used in the method according to the invention.

FIG. 4 is a schematic illustration of various doping profiles which can be created by differently structured energy filters.

FIG. 5 schematically shows the sequence of the doping of the first layer of the donor substrate and a doping profile of the donor substrate resulting therefrom.

FIG. 6 shows various possibilities of the doping profile of the first layer of the donor substrate.

FIG. 7a schematically shows the creation or application of a contact layer in the donor substrate.

FIG. 7b schematically shows a healing step in the donor substrate.

FIG. 8 schematically shows a first variant of the creation of a predetermined breaking site in the donor substrate.

FIG. 9 schematically shows a second variant of the creation of a predetermined breaking site in the donor substrate.

FIG. 10 schematically shows the production of a bonded connection between donor substrate and acceptor substrate.

FIG. 11 schematically shows the splitting of the remaining part of the donor substrate from the composite substrate.

FIG. 12 schematically shows the posttreatment of the surface of the composite substrate in the area of the splitting point.

FIG. 13a schematically shows a cross section through an embodiment of a pretreated composite substrate.

FIG. 13b schematically shows a healing step in the composite substrate.

FIG. 14 schematically shows a cross section through a further embodiment of the pretreated composite substrate and the associated doping profile.

FIG. 15 is a schematic illustration of the splitting of a wafer rod functioning as a donor substrate during use for the multiple creation of a composite substrate from a donor substrate.

FIG. 16 schematically shows the sequence of the doping of the first layer of the donor substrate using masking in some areas of the donor substrate and an alternative doping profile of the donor substrate resulting therefrom.

FIG. 17 schematically shows the cross section of an exemplary base structure of an electronic semiconductor component which was produced using a production method according to the invention.

FIG. 18 schematically shows the cross section of an alternative exemplary base structure of an electronic semiconductor component which was produced using a production method according to the invention.

FIG. 19 schematically shows the cross section of an embodiment of an electronic semiconductor component in the form of a planar MOS transistor.

FIG. 20 schematically shows preferred doping profiles of the electronic semiconductor component.

### DETAILED DESCRIPTION OF SPECIFIC EMBODIMENTS

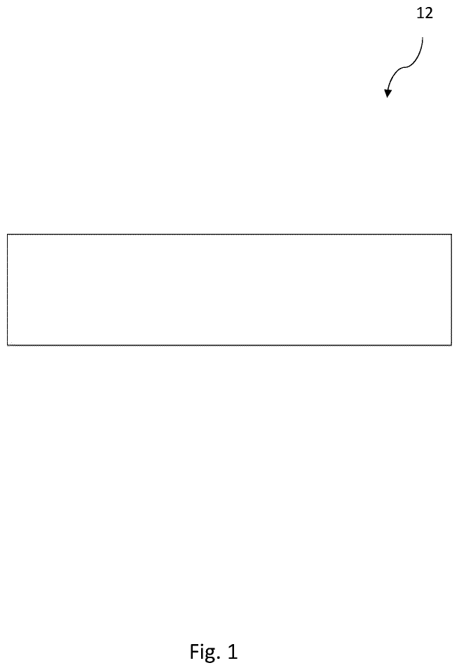

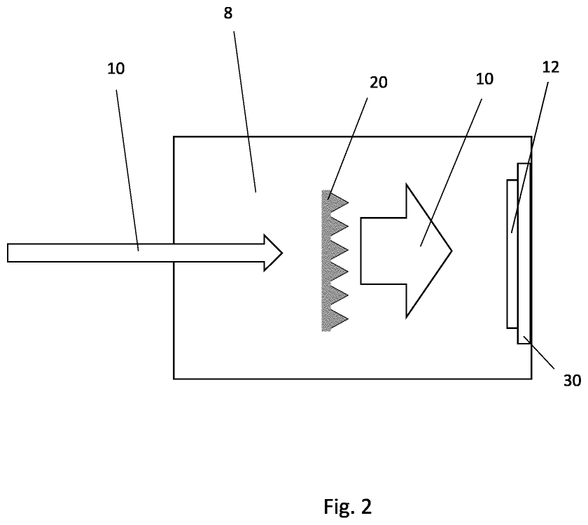

The method for producing an electronic semiconductor component starts, according to a first aspect of the invention, with the provision of a donor substrate 12, which comprises monocrystalline silicon carbide (SiC) or completely consists thereof, see FIGS. 1 and 2.

The embodiment of the donor substrate 12 shown in FIG. 1 is a wafer made of high-quality semi-insulating SiC material having high purity. In particular, this is to be understood as a material in which the concentration of elemental contaminants such as N, B, P is less than 5E15 cm⁻³. Predominantly in this context means that the criterion applies nearly everywhere in the course of the depth profile, but there can be deviations in certain areas, for example at the surface. It is particularly preferably HT-CVD (high-temperature chemical vapor deposition) material.

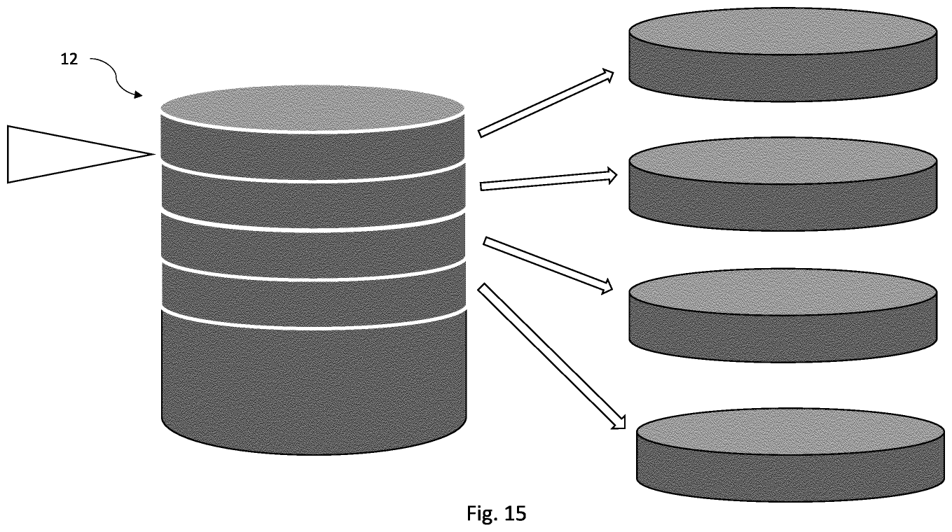

The donor substrate 12 according to FIG. 1 preferably has a thickness of greater than 100 μm, preferably greater than 200 μm, more preferably greater than 300 μm up to 15 cm, preferably up to 10 cm. It can be formed in particular as an undoped or weakly n-doped wafer rod, see FIG. 15.

In one preferred embodiment, the donor substrate is made of SiC of the polytype 4H, 6H, or 3C. These polytypes have proven to be advantageous for the characteristic of the semiconductor components to be produced therewith.

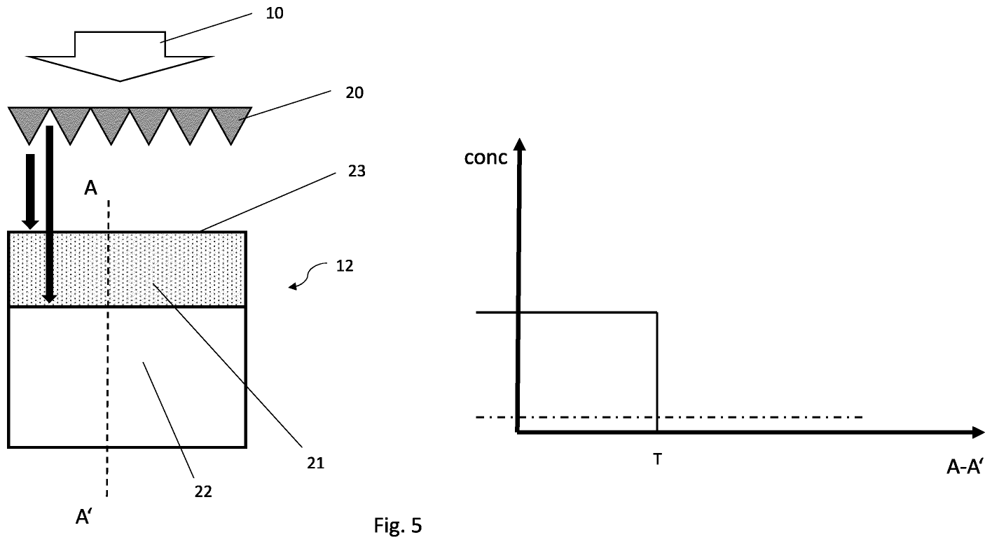

After the provision of the donor substrate 12, the doping of a first layer 21 in the donor substrate 12 (see FIG. 5) takes place, which assumes or partially assumes at least the function of the drift zone (also called active zone or voltage-absorbing zone) later in the finished component. This doping of the first layer 21 in the donor substrate 12 is carried out by ion implantation using an energy filter 20. The corresponding fundamental structure is shown in FIG. 2.

FIG. 2 shows an irradiation chamber 8, in which a high vacuum is typically present. The donor substrate 12 to be doped is accommodated in a substrate holder 30 in the irradiation chamber 8.

An ion beam 10 is generated by a particle accelerator (not shown) and conducted into the irradiation chamber 8. The energy of the ion beam 10 is spread apart there by an energy filter 20 and is incident on the donor substrate 12 to be irradiated. Alternatively, the energy filter 20 can be arranged in a separate vacuum chamber, closable using valves, within the irradiation chamber 8 or directly adjoining the irradiation chamber 8.

The substrate holder 30 does not have to be stationary, but rather can optionally be provided with a device for displacing the donor substrate 12 in x-y (in the plane perpendicular to the sheet plane). In addition, a wafer wheel comes into consideration as a substrate holder 30, on which the donor substrates 12 to be implanted are fixed and which rotates during the implantation. A displacement of the substrate holder 30 in the beam direction (z direction) can also be possible. Furthermore, the substrate holder 30 can optionally be provided with a heater or cooler.

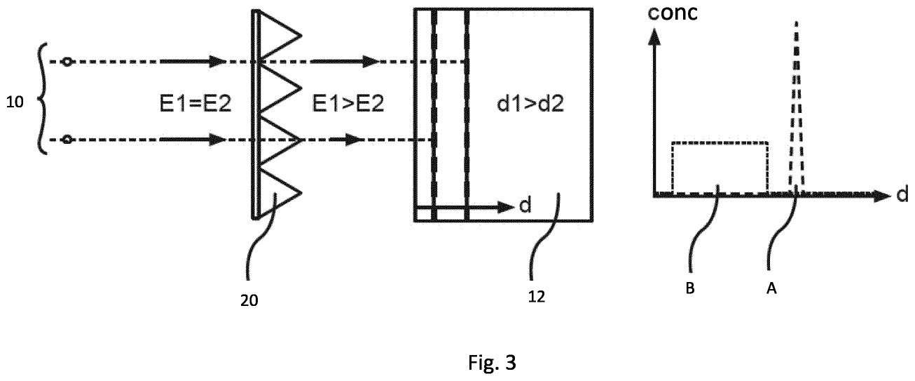

The basic principle of the energy filter 20 is shown in FIG. 3. The monoenergetic ion beam 10 is modified in its energy depending on the entry location during the passage through the energy filter 20 designed as a micro-structured membrane. The resulting energy distribution of the ions of the ion beam 10 results in a modification of the depth profile of the implanted material in the matrix of the donor substrate 12. E1 designates the energy of a first ion, E2 designates the energy of a second ion, conc designates the doping concentration, and d designates the depth in the donor substrate 12. The typical Gaussian distribution is identified by reference sign A on the right in the diagram, which results without the use of an energy filter 20. In contrast, a rectangular distribution is sketched by way of example with reference sign B, which can be achieved upon use of an energy filter 20.

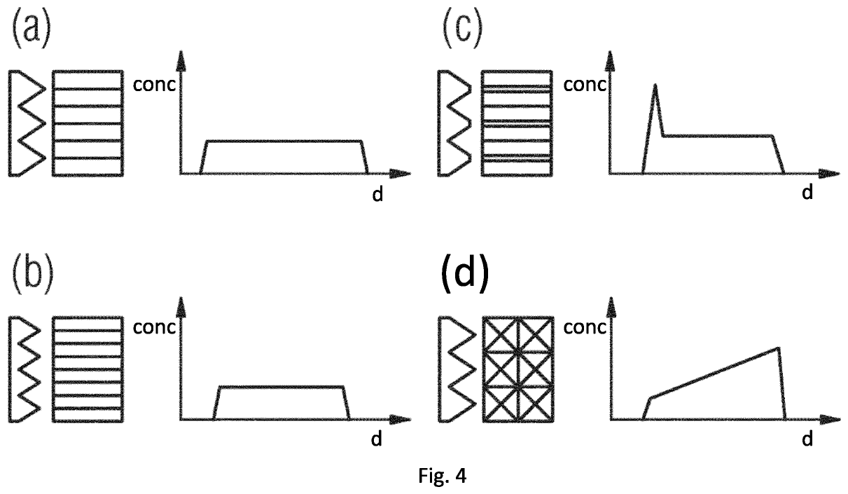

The layouts or three-dimensional structures of energy filters 20 shown in FIG. 4 show the fundamental possibilities for creating a large number of dopant depth profiles by energy filter 20. conc again designates the doping concentration and d again designates the depth in the donor substrate 12. The filter structure profiles can in principle be combined with one another to obtain new filter structure profiles and thus new dopant depth profiles.

Such energy filters 20 are generally produced from silicon. They have a thickness of between 3 μm and 200 μm, preferably between 5 μm and 50 μm, and particularly preferably between 7 μm and 20 μm. They can be held in a filter frame (not shown). The filter frame can be accommodated exchangeably in a filter holder (not shown).

For the preferred formation of an n-doped first layer 21, implantation using ions of nitrogen or phosphorus is particularly suitable, while implantation using ions of boron or aluminum is particularly suitable for a p-doped layer.

In the exemplary embodiment of the method step of the doping of the first layer 21 shown in FIG. 5, the ion implantation in the donor substrate 12 takes place from a front side of the donor substrate 12. The surface of the donor substrate 12 facing toward the ion beam is designated hereinafter as the outer face 23. The short, solid black arrow indicates the ions of minimal energy transmitted through the energy filter 20, and the long, solid black arrow indicates the ions of maximum energy transmitted through the energy filter 20. The resulting doping profile along section A-A′ is shown on the right in the coordinate system. conc stands for the doping concentration. The doping profile is based on the design of the donor substrate 12 according to FIG. 1 and is approximately uniform over the entire first layer 21. The first layer 21 extends from the outer face 23 of the donor substrate 12 facing toward the ion beam 10 to a predetermined doping depth T, where a remaining part 22 of the donor substrate 12 adjoins, which is not affected by the ion implantation by energy filter.

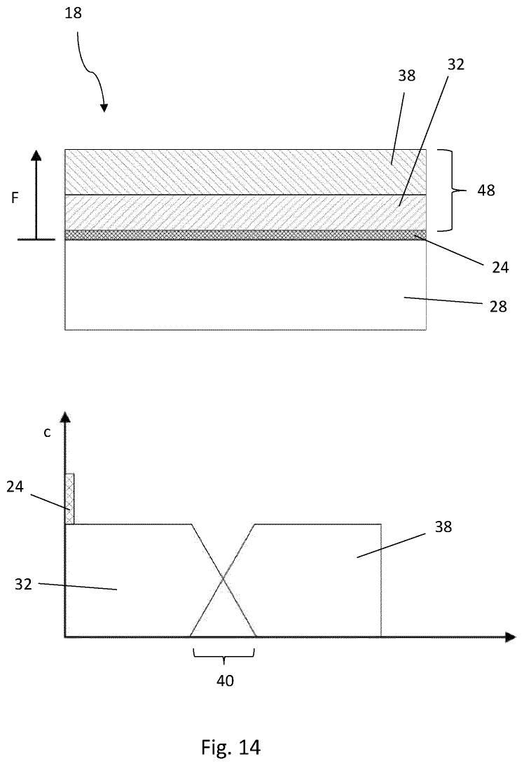

The thickness of the first layer 21 preferably substantially corresponds to a previously determined thickness of the active layer in the later component or a combination of active layer plus a field stop layer or a combination of active layer plus a field stop layer and a superficial functional zone. The total thickness of the first layer 21 is thus determined by the type and above all the voltage class of the semiconductor component to be produced. The higher the voltage class, the thicker the first layer 21. For particularly high voltage classes, reference is made to FIG. 14 and the associated description.

The thickness of the first layer 21 is preferably between 3 and 15 μm. This corresponds to the presently reasonable possible doping depth T of the above-mentioned preferred ion types in SiC.

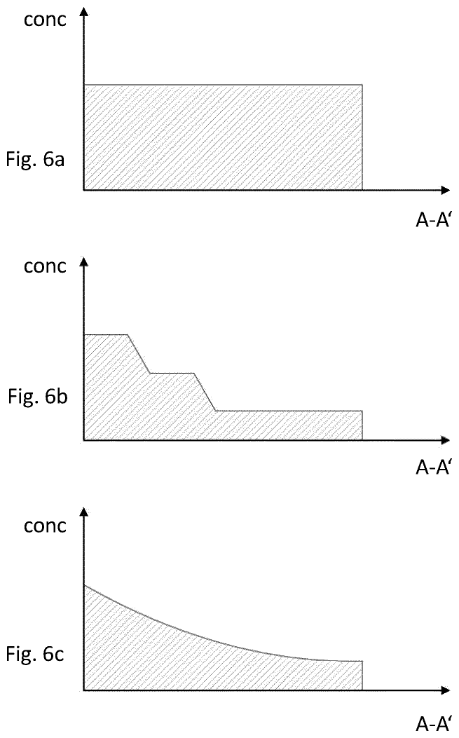

FIGS. 6a to 6c show possible preferred doping profiles in the first layer 21 of the donor substrate 12.

In principle, the doping of the first layer 21 supplies p-doping or n-doping having a doping concentration (conc) in the first layer 21 of 1E15 cm⁻³ to 5E17 cm⁻³.

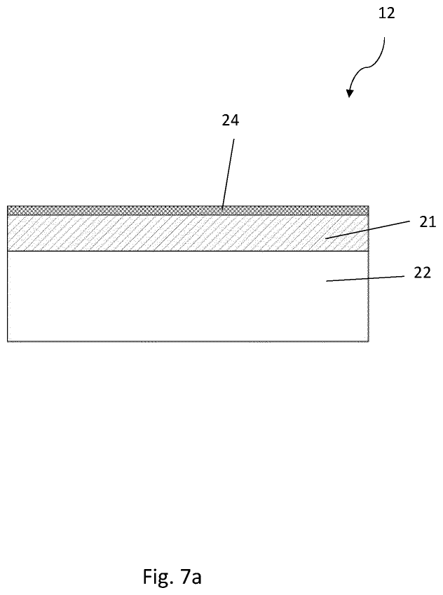

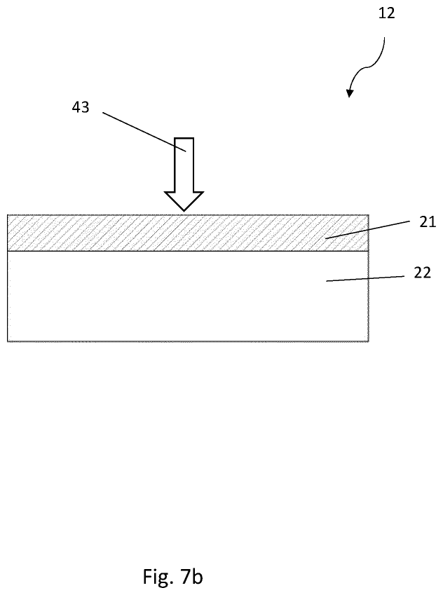

FIG. 7a shows the result of the optional step of creating a contact layer 24 in a superficial area of the first layer 21 or applying a contact layer 24 to the surface of the first layer 21.

The contact layer 24 is preferably created by ion implantation in the first layer 24. The contact layer 24 has a thickness of only 10 nm up to 1 μm here. Preferably ions of P, N, or Al are used for the implantation (without energy filter).

The dopant concentration in the contact layer 24 is preferably at least 100 times, more preferably at least 1000 times, more preferably at least 10,000 times, still more preferably at least 100,000 times above a mean dopant concentration in the remainder of the first layer 21 or in the first layer 21.

The dopant concentration in the contact layer 24 is preferably greater than 1E17 cm⁻³, more preferably greater than 1E19 cm⁻³.

It is also possible to apply a thin contact layer 24, for example, a few nanometers thick, to the first layer 21. This is carried out, for example, by sputter deposition, vapor deposition, or a CVD deposition method. The contact layer 24 does not have to be completely covered; it can also consist of nanoparticles.

Simultaneously or after the layer application of the contact layer 24, a further treatment of the surface can take place, for example, physical back etching.

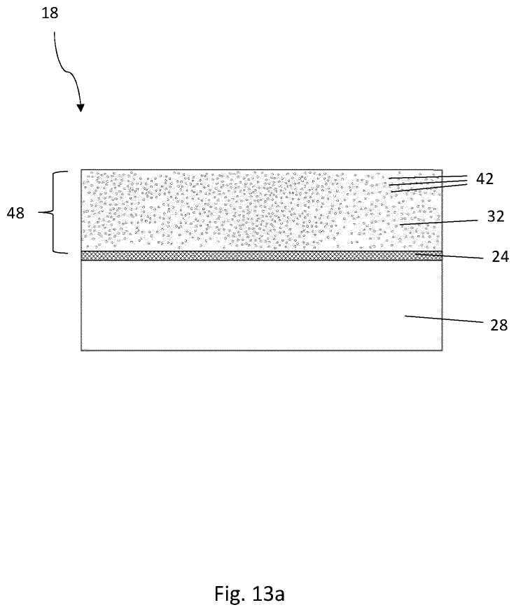

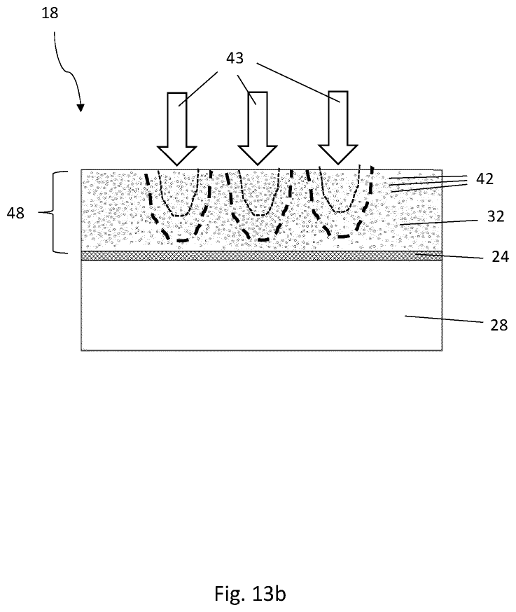

As shown in FIG. 7b, after completed ion implantation in the donor substrate 12, possibly also after completed production of the contact layer, there is a first possibility for carrying out a healing step by laser irradiation 43. This is only schematically indicated by the arrow 43 in the drawing. In actuality, the laser irradiation 43 will be carried out at many different points of the donor substrate 12. More details on the healing step are explained further below with reference to FIG. 13b.

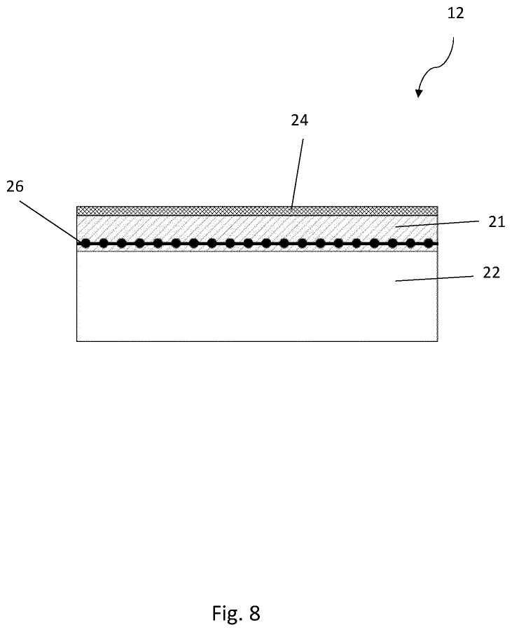

In the next step, according to FIG. 8, a predetermined breaking site 26 is created in the donor substrate 24. The predetermined breaking site 26 in the example of FIG. 8 is in the area of the first layer 21, preferably in an end area of the first layer 21 close to the predetermined doping depth T, wherein the predetermined breaking site 26 is preferably not further than 1 μm, more preferably not further than 500 nm, particularly preferably not further than 100 nm distance from the doping depth T and thus from the end of the first layer 21. In particular in rectangular profiles with a falling flank, the predetermined breaking site 26 is still to be in the area of the plateau.

The creation of the predetermined breaking site 26 is preferably carried out by ion implantation of split-triggering ions, which are schematically shown as black dots in FIG. 8. No energy filter is used here. According to FIG. 8, the split-triggering ions are introduced over the entire width of the donor substrate 12. The split-triggering ions are preferably selected from the following: H, H₂, He, B. The split-triggering ions are high-energy ions having an energy between 0.5 and 10 MeV, preferably between 0.5 and 5 MeV, more preferably between 0.5 and 2 MeV. For hydrogen, at an ion energy of 0.6 MeV, a formation of the predetermined breaking site 26 results in a depth of approximately 5 μm, at an ion energy of 1.0 MeV at a depth of approximately 10 μm, and at an ion energy of 1.5 MeV at a depth of approximately 20 μm.

A particle dose of the split-triggering ions is preferably in each case between 1E15 cm⁻² and 5E17 cm⁻². The energy sharpness (ΔE/E) of the ion beam of the split-triggering ions is preferably less than 10⁻², more preferably less than 10⁻⁴. During the implantation of the split-triggering ions, it is advantageous if the temperature in the donor substrate 12 remains below 300° C., preferably below 200° C. For this purpose, the chuck on which the donor substrate 12 lies is cooled if necessary.

Using these parameters, a doping profile is created which has a sharp peak (see the Gaussian distribution identified by A in FIG. 3). In this way, it is ensured that the predetermined breaking site 26 has a high doping distributed on an extremely low thickness. The variation of the range of the ions in the donor substrate 12 (longitudinal straggling σ) is, depending on the primary energy of the ion beam, only between 100 nm and 500 nm, preferably between 200 nm and 400 nm.

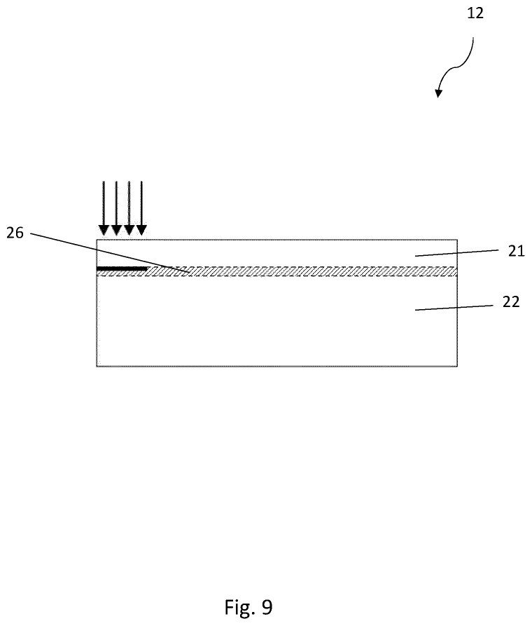

Alternatively, as shown in FIG. 9 on the basis of the arrows and the horizontal black bar, the split-triggering ions can be introduced over only a part of the width of the donor substrate 12, preferably only in one or in both edge areas of the donor substrate 12. The predetermined breaking site 26 is predefined in some sections in this way.

Alternatively to the ion implantation, the predetermined breaking site 26 can also be formed by electron irradiation or laser irradiation.

At this point, a healing step for implantation defects can take place for the first time or again, preferably by laser irradiation as shown in FIG. 7b.

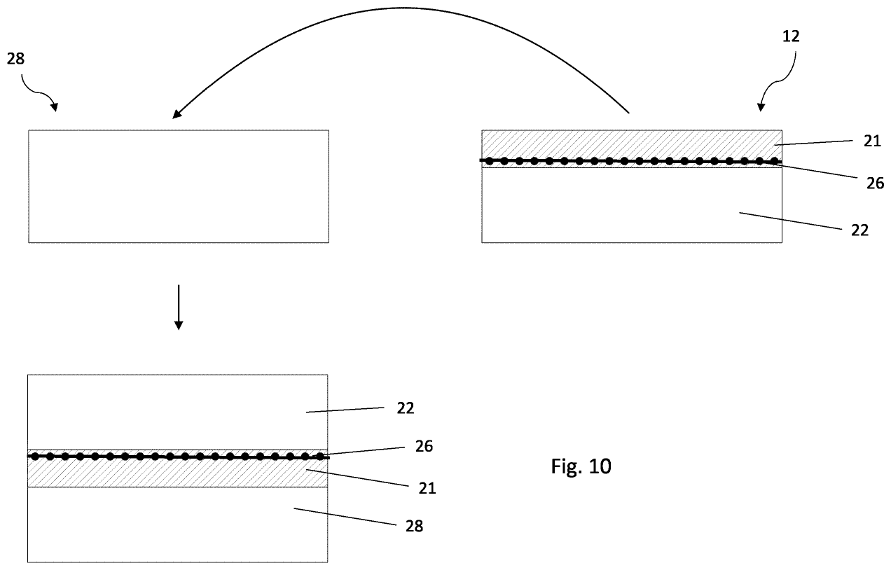

The donor substrate 12 is then bonded with the side of the first layer 21 in front by a bonded connection to the acceptor substrate 28, as outlined in FIG. 10. The first layer 21 is therefore arranged in an area between the acceptor substrate 28 and the remaining part 22 of the donor substrate 12. It is irrelevant whether the donor substrate 12 is moved toward the acceptor substrate 28 for the production of the bonded connection, as shown by the curved arrow in FIG. 10, which also indicates the turning over of the donor substrate 12, or the acceptor substrate 28 is moved toward the donor substrate 12.

The intermediate result of the bonding process is shown on the bottom-left in FIG. 10. The layer sequence could also be inverted, for example, if the acceptor substrate 28 was moved toward the donor substrate 12.

The contact layer 24 was not shown in either case in FIGS. 9 and 10, but it is preferably present. In this case, the production of the bonded connection between donor substrate 12 and acceptor substrate 28 takes place via the contact layer 24, wherein the following sequence results: acceptor substrate 28, contact layer 24, remaining part of first layer 21 or first layer 21, remaining part 22 of the donor substrate 12.

The production of a low-ohmic bonded connection is preferably carried out by a temperature treatment of the substrate obtained as the intermediate result at a temperature of between 800° C. and 1400° C., more preferably between 900° C. and 1300° C.

Before the step of the production of the bonded connection, a pretreatment of at least one, preferably both surfaces to be bonded can take place, in particular a wet chemical treatment, plasma treatment, or ion beam treatment. One treated surface can also be the contact layer 24. An application of a thin layer, a few nanometers thick, to produce a later low-ohmic connection of acceptor substrate 28 and donor substrate 12 is also conceivable. In principle, an extremely low-ohmic contact between acceptor substrate 28 and donor substrate 12 is important.

In principle, a permanent bonded connection between acceptor substrate 28 and donor substrate 12 is preferred, which also remains in existence in the resulting semiconductor component. However, a temporary bonded connection or fixing between acceptor substrate 28 and donor substrate 12, for example for a few process steps, is also conceivable. This opens up the possibility of carrying out further process steps, for example, by ion implantation and possibly a subsequent healing step, after removal of the acceptor substrate from the side then exposed.

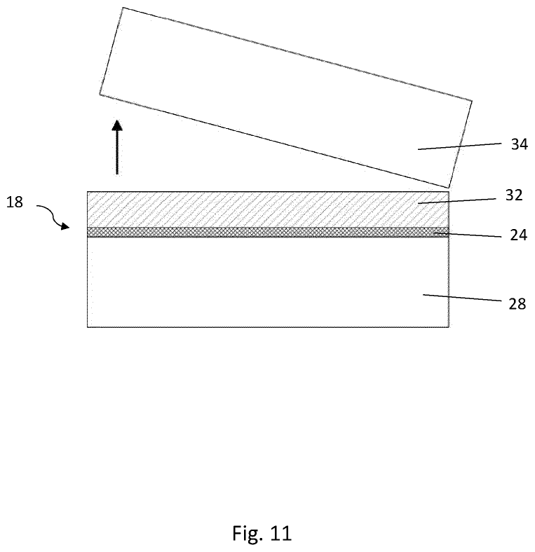

FIG. 11 schematically shows the step of splitting the donor substrate 12 in the area of the predetermined breaking site 26, by which a pretreated composite substrate 18 is created, which comprises the acceptor substrate 28 and a doped layer 32 connected thereto, wherein the doped layer 32 comprises at least a section of the first layer 21 of the donor substrate 12. The part 34 of the donor substrate 12 split off of the acceptor substrate 28 is removed.

The splitting of the donor substrate 12 is preferably triggered by a temperature treatment of the composite substrate 18 at a temperature of between 600° C. and 1300° C., preferably between 750° C. and 1200° C., more preferably between 850° C. and 1050° C. In one embodiment, see FIGS. 8 and 9, gas bubbles are formed due to the implanted ions, which grow together and result in the splitting.

Alternatively, external forces can be exerted on the composite substrate 18, so that the donor substrate 12 breaks off along the predetermined breaking site 26. A combination of heat treatment and external forces can also be necessary or helpful. Exerting external forces is unavoidable in particular if ions were only introduced in some sections into the donor substrate 12.

If both the production of the bonded connection and the splitting of the donor substrate 12 are carried out by a temperature treatment, both steps can be carried out simultaneously under certain circumstances.

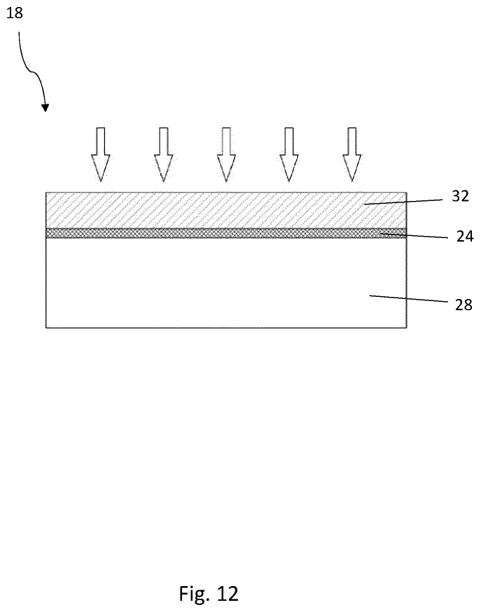

In addition, as schematically shown by the arrows in FIG. 12, after the step of splitting, a posttreatment of the first surface of the composite substrate 18 can be carried out in the area of the predetermined breaking site 26, in particular by polishing and/or removing defects and/or grinding. Chemical-mechanical polishing is a preferred method.

Implantation defects 42, which are schematically shown in FIG. 13a, can finally be healed in the doped layer 32 of the pretreated composite substrate 18.

The healing step is preferably carried out by laser irradiation 43 and is schematically shown in FIG. 13b. The desired temperature distribution is preferably achieved by suitable selection of irradiation points or areas and the parameters of the laser beam. In this way, defects can be healed in surface-proximal areas, while a lower temperature is maintained in deeper layers of the substrate. Three irradiation points are shown by way of example in FIG. 13b with schematically shown lines of equal temperature (for example: dotted 1650° C.; dashed 1500° C.). A desired temperature gradient is achieved by superimposing diverse temperature introductions.

The composite substrate 18, which is used as the basis for the further processing to form an electronic semiconductor component, is shown once again in FIG. 13a. It comprises the acceptor substrate 28 and the doped layer 32 bonded thereto and made of monocrystalline SiC. In addition, it can have the contact layer 24 between acceptor substrate 28 and doped layer 32.

The doped layer 32 preferably has a thickness of 3 μm to 30 μm, more preferably of 3 μm to 15 μm. It is preferably made of SiC of the polytype 4H, 6H, or 3C. The doped layer 32 preferably has a p-doping or n-doping having a doping concentration of 1E15 cm⁻³ to 5E17 cm⁻³. The doped layer 32 was preferably doped using ions from one of the following elements as the dopant: N, P, B, or Al.

The dopant depth profile of the doped layer 32 preferably substantially results from an inversion of the dopant depth profile of the first layer 21 in the donor substrate 12.

The doped layer 32 can thus, for example, have a substantially constant dopant depth profile.

The doped layer 32 can also have a dopant depth profile rising in steps in the direction of the acceptor substrate 28, wherein the steps in an area of the doped layer 32 facing toward the acceptor substrate 28 are formed by up to 40%, preferably up to 30% of the total depth of the doped layer 32.

The doped layer 32 can also supply a dopant depth profile rising continuously in the direction of the acceptor substrate 28.

The implantation defect profile substantially follows the implanted foreign atom concentration depth profile.

FIG. 14 shows an alternative embodiment of the pretreated composite substrate 18 in cross section and underneath this a dopant concentration profile along the section of the composite substrate 18 according to arrow F. This is particularly suitable for the production of very high-blocking components, for example >600 V.

In this case, the pretreated composite substrate 18 has, in addition to the doped layer 32, a supplementary doped layer 38 made of monocrystalline SiC. An overlapping area 40 of the respective dopant depth profiles is preferably present in a transition section between the doped layer 32 and the supplementary doped layer 38.

In the embodiment shown in FIG. 13a, the required active layer (drift zone, voltage-absorbing layer) of the later semiconductor component is formed solely by the doped layer 32 and thus simultaneously by the first layer 21 or a (preferably large) part of the first layer 21 in the donor substrate 12.

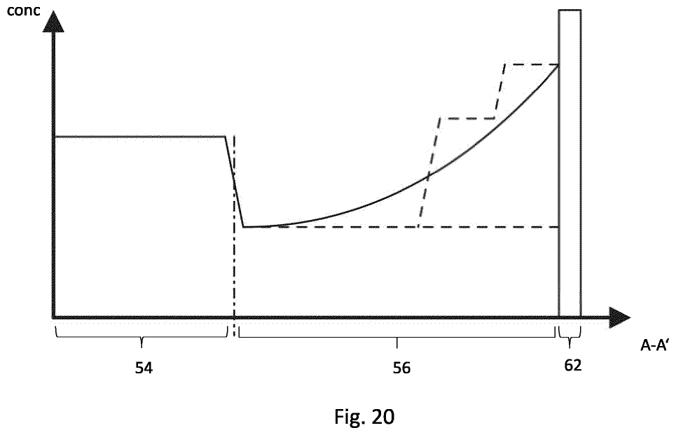

In contrast, the active layer is formed in embodiments as in FIG. 14 by a combination of the doped layer 32 and the supplementary doped layer 38. While a substantially constant summation doping profile results in FIG. 14 by superposition of the two partial profiles, arbitrary other doping profiles can also be formed by concatenation and partial overlap of the doping profiles in doped layer 32 and supplementary doped layer 38. The combined overall doping profile made up of the combination of both dopant depth profiles of the doped layer 32 and the supplementary doped layer 38 can thus also be a profile rising in steps toward the acceptor substrate 28 or a profile rising continuously toward the acceptor substrate 28. Further particularly preferred doping profiles are described in more detail below with reference to FIG. 20.

In each of these embodiments, the reference sign 48 designates the first section of the donor substrate 12, which remains in each case after the splitting as part of the composite substrate 18. This first section 48 can either be composed solely of the doped layer 32, if no supplementary doped layer 38 is present (FIG. 13a), or of a combination of the doped layer 32 and the supplementary doped layer 38 (FIG. 14, FIG. 20).

Such combined profiles are obtained in that the predetermined breaking site 26 in the donor substrate 12 is not created within the first layer 21, but rather in the remaining part 22 of the donor substrate 12, which was not doped by ion implantation in the donor substrate 12.

After the splitting at the predetermined breaking site 26 as in FIG. 11, the doping of the supplementary doped layer 38 can then be carried out from the side facing away from the acceptor substrate 28 by a further ion implantation by energy filter. The statements made above on FIGS. 2 to 6 on ion implantation by energy filter apply identically to the ion implantation in the supplementary doped layer 38. The thickness of the supplementary doped layer 38 is generally between 3 and 15 μm. Total thicknesses of the active zone doped by ion implantation of up to 30 μm are thus obtained.

Following the implantation, a healing step can take place by laser irradiation 43, which eliminates the defects in the supplementary doped layer 38.

In principle, two or more composite substrates 18, even a large number of composite substrates 18, can be produced from one donor substrate 12, if the donor substrate 12 from FIG. 1 is at least twice as thick as the thickness of the required doped layer 32 in the composite substrate 18. The effect is particularly high with a thick wafer rod as the donor substrate 12. Substantial costs can be saved in the production in this way. This is schematically shown in FIG. 15.

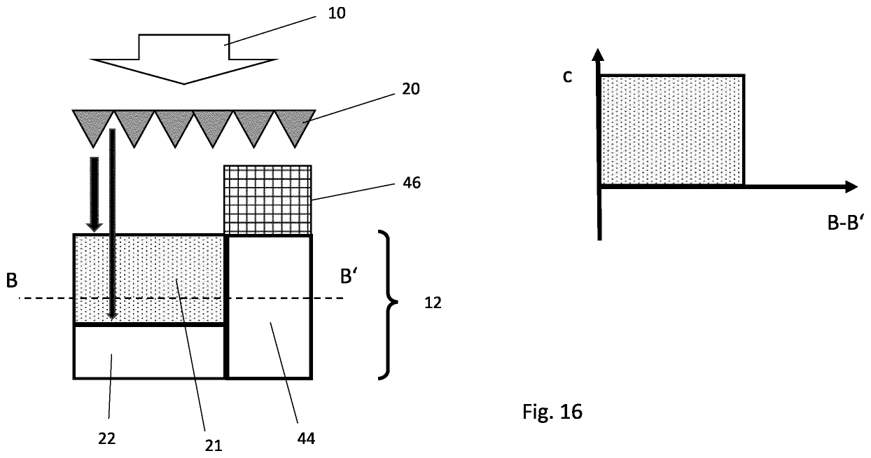

As shown in FIG. 16, during the ion implantation by energy filter 20 in the first layer 21 of the donor substrate 12 (and/or in the supplementary doped layer 38 of the composite substrate 18), a mask 46 can be used to create one or more undoped areas 44 in the first layer 21 of the donor substrate 12 (and/or in the supplementary doped layer 38 of the composite substrate 18).

The composite substrate 18 can become a finished semiconductor component 50 by way of further steps, for example, by way of implanting further active regions, creating oxides, depositing gate electrodes, contacts, lines or vias, etc.

After this component processing, a healing step can take place again or for the first time by laser irradiation 43. Defects of, for example, source-drain contact implantation, channel implantation, p-JFET implantation, etc. can be healed in the process. This healing can possibly also take place simultaneously with the healing of the defects in the supplementary doped layer 38 or, if no supplementary doped layer is present, in the doped layer 32.

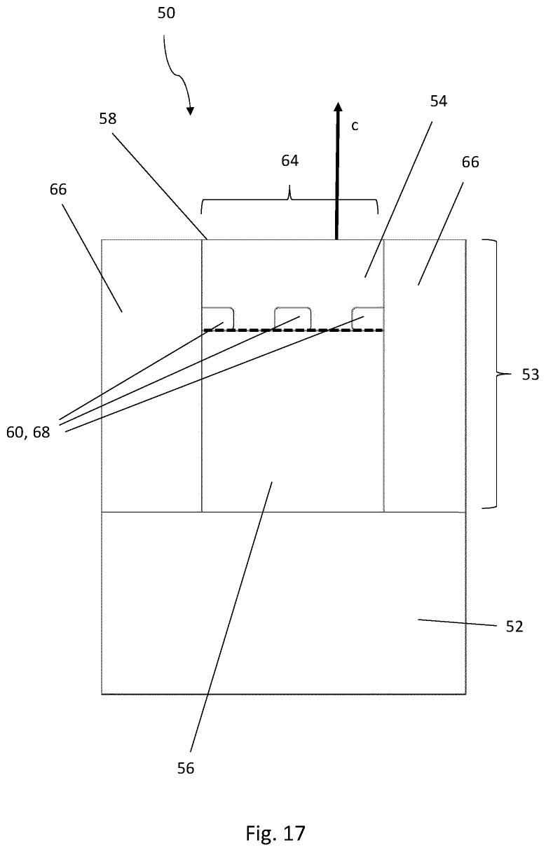

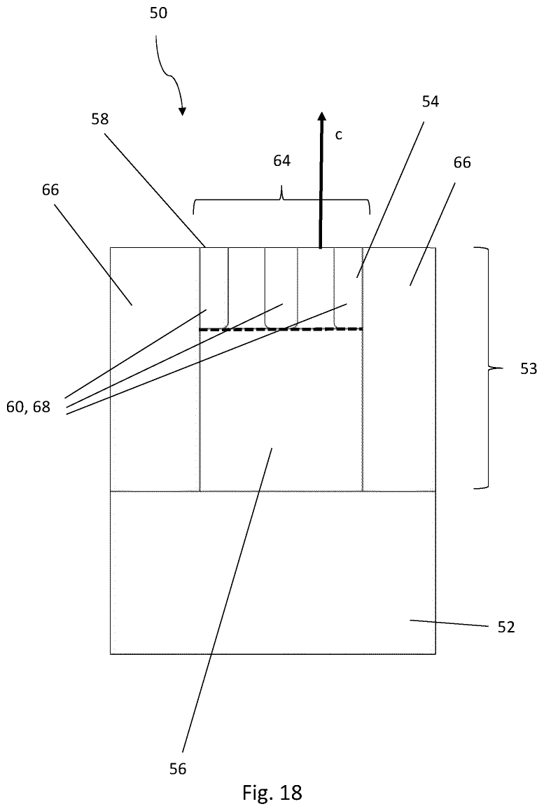

Two fundamental base structures of electronic semiconductor components 50 produced using the method are shown in FIGS. 17 and 18.

The first base structure from FIG. 17 comprises a carrier substrate 52, which normally corresponds to the acceptor substrate 28 of the pretreated composite substrate 18. The carrier substrate 52 normally consists of a highly-doped material and is generally field-free.

A crystal 53 made of SiC is applied to the carrier substrate 52. This crystal 53 normally corresponds to the first section 48 of the donor substrate 12 of the pretreated composite substrate 18.

The electronic semiconductor component 50 comprises an active component area 64, which has a first zone 54 in the area of the first surface 58 and a second zone 56 adjoining the first zone 54 in the depth direction.

The first zone 54 comprises a surface-proximal shielding structure 60 or JFET structure in an area which comprises at least subsections of the first surface 58 of the crystal 53. The shielding structure or J-FET structure is characterized by a p⁺/n transition interrupted in one direction, i.e., a p⁺ region is formed in some regions (not continuously) and generally cannot be cleared. The areas with p+ doping are identified by reference sign 68.

The second zone 56 comprises a voltage-absorbing layer (also called drift zone or active layer) or consists thereof. The transition between the first zone 54 and the second zone 56 is identified by the dashed line. The thickness of the second zone 56 is preferably between 2 μm and 50 μm.

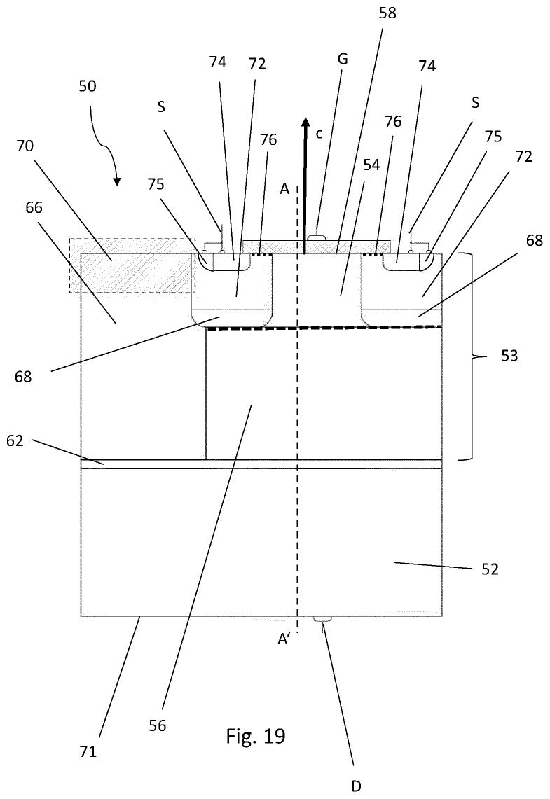

As shown in FIG. 19, the semiconductor component 50 moreover comprises a field-free contact zone or field stop zone 62 at the transition between the second zone 56 and the carrier substrate 52. This field stop zone 62 normally corresponds to the contact layer 24 of the pretreated composite substrate 18. The field-free contact zone or field stop zone 62 has a vertical thickness of at most 2 μm, preferably at most 1 μm.

A non-active edge area 66 laterally surrounds the first zone 54 and the second zone 56 substantially completely.

The second base structure of the semiconductor component 50 shown in FIG. 18 corresponds in essential parts to the base structure from FIG. 17. Identical reference signs designate identical elements. The difference is that the p⁺ regions 60 are not trenched regions, but rather are formed continuously up to the first surface 58.

All p-doped shielding structures 60 have multiple common features, independently of the respective type of the semiconductor component 50. The shielding structures 60 are not formed continuously, but rather periodically interrupted, parallel to the first surface 58. The distances are formed because of the distance to the first surface 58 so that the maximum tolerable field strength at the first surface 58 is reliably not exceeded in blocking operation in the “open” areas. The shielding structures 60 are connected either directly or via lines (third dimension, not shown) to the source potential, gate potential, or anode potential. The shielding structures 60 are either located isolated (except for the electrical connection) embedded in an n-region or they are formed as doped regions having a high aspect ratio starting from the first surface 58. The typical depths of the p-n transition are between 500 nm and 3.0 μm. The shielding structures 60 are so highly doped that the regions are not cleared even in the case of maximum blocking voltage.

The spatial delimitation between first zone 54 and second zone 56 illustrated by the dashed line in FIG. 17 and FIG. 18 is typically at the point at which the p-doped regions 68 end in the depth direction of the crystal 53. The transition is typically defined in the present description as parallel to the first surface 58.

The exemplary embodiment of the electronic semiconductor component 50 shown in FIG. 19 only shows a detail of the semiconductor component 50. The respective right flank can be seen as a cutaway flank.

FIG. 19 shows a vertical power semiconductor component 50 in the form of a planar MOS transistor. The nonactive edge area 66, except for a possibly existing surface-proximal edge structure 70, is preferably nominally undoped. Reference sign 52 again designates the carrier substrate, reference sign 53 again designates the SiC crystal, reference sign 54 again designates the first zone, reference sign 56 again designates the second zone, reference sign 62 again designates the field stop zone, and reference sign 68 again designates the p⁺ regions of the shielding structure. A metal contact 71 is applied to the lower side of the carrier substrate 52. G designates the gate electrode, S designates the source electrode, and D designates the drain electrode. Reference sign 72 designates p-regions (p-well) and reference sign 74 designates n+ regions. Reference sign 75 designates further p+ regions. The first surface 58 of the crystal 53 is formed planar here and preferably extends over the entire width of the semiconductor component 50. Gate oxides are explicitly not considered to be part of the first surface 58.

Many further forms of semiconductor components exist which can be produced using a method according to the invention.

The doping profile (conc) shown in FIG. 20 of the semiconductor component 50 from FIG. 19 has, in the area of the second zone 56, a profile rising continuously in the depth direction, as was already described above with respect to the pretreated composite substrate 18. Alternatively, the doping profile can also extend consistently in the area of the second zone 56 or can be a profile rising in steps in the end area of the second zone 56, as indicated by the dashed lines. With reference to FIGS. 6a to 6c, it was already described in detail above how such doping profiles are to be obtained.

It is now preferred that, in addition, in the area of the first zone 54, the doping profile has a plateau which is higher than the doping in the area of the second zone 56 adjoining thereon. In general, the area of the first zone 54 and the area of the second zone 56 are each n-doped. The doping concentration in the n-doped area of the first zone 54 is preferably higher by a factor of 1.5 to 100, particularly preferably by a factor of 2 to 10, than in an n-doped area of the second zone 56 facing toward the first zone 54. The falling flank of the doping profile is normally not completely perpendicular.

Of course, a doping deviating from the profile shown is obtained in the p+ regions 68 of the first zone 54. A doping concentration in a p⁺ region 68 of the first zone 54 is preferably higher by a factor of 2 to 1000, particularly preferably by a factor of 50 to 1000, than a doping concentration in an n-doped area of the second zone 56 facing toward the first zone 54.

Contrary to FIG. 20, it is also possible that the doping profile in the first zone 54 and the second zone 56 adjoin one another substantially flush. This is self-explanatory if the first zone 54 and the second zone 56 were doped by the same implantation process (as the doped layer 32 in the donor substrate 12). However, this is also possible if the first zone 54 is first doped in a downstream implantation process (for example as the supplementary doped layer 38).

The doping profiles of the second zone 56 from FIG. 20 are also fundamentally applicable to many other semiconductor components 50.

In the scope of the invention, “connected” is understood as connected directly or indirectly, i.e., with a further element interposed. A “connection” between two elements can also be direct or indirect.

1.-62. (canceled)

63. A method for producing an electronic semiconductor component via the intermediate step of creating a pretreated composite substrate, wherein the pretreated composite substrate comprises an acceptor substrate and a first section of a donor substrate, which first section has at least one doped layer, wherein the method comprises the steps of:
a) providing a donor substrate, which comprises monocrystalline SiC;
b) doping a first layer in the donor substrate by ion implantation, wherein a predetermined dopant depth profile is created in the first layer of the donor substrate during the doping, wherein the first layer extends from the outer face of the donor substrate facing toward the ion beam to a predetermined doping depth, where a remaining part of the donor substrate adjoins;
c) creating a predetermined breaking site in the donor substrate which extends substantially parallel to the outer face of the donor substrate;
d) providing the acceptor substrate and producing a connection between donor substrate and acceptor substrate, wherein the first layer is arranged in an area between the acceptor substrate and the remaining part of the donor substrate;
e) splitting the donor substrate in the area of the predetermined breaking site to create the pretreated composite substrate, wherein the pretreated composite substrate comprises the acceptor substrate and a first section of the donor substrate connected thereto, which first section has at least one doped layer, wherein the doped layer comprises at least one section of the first layer of the donor substrate, and wherein the pretreated composite substrate, after the splitting, has a first surface in the area of the predetermined breaking site,
f) introducing at least one further structural element of the semiconductor component into the composite substrate from the first surface and/or arranging at least one further structural element of the semiconductor component on the first surface,
wherein at least after one of steps b), c), e) and/or after or during step f), a healing step for implantation defects is carried out in the first layer of the donor substrate and/or in the first section of the donor substrate by laser irradiation.

64. The method of claim 63, wherein a healing step by laser irradiation is carried out after step e) and/or after or during step f).

65. The method of claim 64, wherein the healing step after step e) and/or after or during step f) is performed by laser irradiation onto the first surface of the composite substrate.

66. The method of claim 64, wherein, during the healing step by laser irradiation after step e) and/or after or during step f), the temperature in the area of the acceptor substrate does not exceed 1400° C.

67. The method of claim 64, wherein, during the healing step by laser irradiation after step e) and/or after or during step f), a temperature gradient is formed in the composite substrate, wherein the temperature is higher close to the first surface than in the acceptor substrate.

68. The method of claim 67, wherein the temperature in the doped layer during the healing step by laser irradiation after step e) and/or after or during step f) is at least temporarily at least 1450° C.

69. The method of claim 67, wherein the predetermined breaking site is in the area of the remaining part of the donor substrate, and, in addition, after step e), before the healing step, the further step of an ion implantation, preferably using an energy filter, in the composite substrate from the first surface is carried out, by which a supplementary doped layer is formed.

70. The method of claim 69, wherein the ion implantation in the composite substrate extends at least up to the doped layer.

71. The method of claim 70, wherein the ion implantation in the composite substrate is carried out in a manner such that a doping concentration in the supplementary doped layer is higher than a doping concentration in an area of the doped layer facing toward the supplementary doped layer.

72. The method of claim 69, wherein the temperature in the supplementary doped layer during the healing step by laser irradiation after step e) and/or after or during step f) is at least temporarily at least 1450° C.

73. The method of claim 63, wherein a healing step by laser irradiation is carried out after at least one of steps b) and c).

74. The method of claim 73, wherein the healing step by laser irradiation after at least one of steps b) and c) takes place on the outer face of the donor substrate.

75. The method of claim 73, wherein, during the healing step by laser irradiation after at least one of steps b) and c), the temperature in the area of the remaining part of the donor substrate does not exceed 1450° C.

76. The method of claim 73, wherein, during the healing step by laser irradiation after at least one of steps b) and c), a temperature gradient is formed in the donor substrate, wherein the temperature in the first layer is higher than the temperature in the remaining part of the donor substrate.

77. The method of claim 76, wherein the temperature in the first layer during the healing step by laser irradiation after at least one of steps b) and c) is at least temporarily at least 1450° C.

78. The method of claim 63, wherein a healing step is carried out by pulsed introduction of light.

79. The method of claim 78, wherein between 100 and 5000 individual pulses are deposited per irradiation point.

80. The method of claim 78, wherein, during a healing step, the temperature introduction in the depth and/or the temperature gradient is controlled by sequential or simultaneous application of light of different wavelengths, pulse durations, and/or pulse numbers.

81. The method of claim 78, wherein a pulse frequency is in the range of 20 Hz to 3 kHz.

82. The method of claim 78, wherein a pulse width is in the range of 1 to 1000 ns.

83. The method of claim 78, wherein a wavelength of the light is in the range between 250 and 400 nm.

84. The method of claim 63, wherein the first layer has a thickness of 3 to 15 μm.

85. The method of claim 63, wherein the doping of the first layer applies an n-doping having a doping concentration in the first layer of 1E15 cm⁻³ to 5E17 cm⁻³.

86. The method of claim 63, wherein the doping of the first layer is performed using ions of one of the following elements: nitrogen, phosphorus, boron, or aluminum.

87. The method of claim 63, wherein the acceptor substrate is only temperature stable up to at most 1400° C.

88. The method of claim 87, wherein the acceptor substrate is formed from silicon.

89. The method of claim 63, wherein the doping in step b) is performed using an energy filter, wherein the energy filter is a micro-structured membrane having a predefined structure profile for setting a dopant depth profile, induced by the implantation, in the first layer in the donor substrate.

90. A method for producing an electronic semiconductor component, which comprises the steps of:
providing a pretreated composite substrate, wherein the pretreated composite substrate has an acceptor substrate and at least one doped layer made of SiC, which is connected to the acceptor substrate,
carrying out a healing step for implantation defects in the doped layer by laser irradiation, wherein the temperature in the area of the acceptor substrate does not exceed 1400° C.

91. The method of claim 90, wherein the doped layer has a first surface, which faces away from the acceptor substrate, and the laser irradiation takes place on the first surface.

92. The method of claim 90, wherein, during the healing step by laser irradiation, a temperature gradient is formed in the composite substrate, wherein the temperature is higher close to the first surface than in the acceptor substrate.

93. The method of claim 90, wherein the temperature in the doped layer during the healing step by laser irradiation is at least temporarily at least 1450° C.

94. The method of claim 90, wherein the healing step is performed by pulsed introduction of light.

95. The method of claim 93, wherein between 100 and 5,000 individual pulses are deposited per irradiation point.

96. The method of claim 90, wherein, during the healing step, the temperature introduction in the depth and/or the temperature gradient is controlled by sequential or simultaneous application of light of different wavelengths, pulse durations, and/or pulse numbers.

97. The method of claim 90, wherein a pulse frequency is in the range of 20 Hz to 3 kHz.

98. The method of claim 90, wherein a pulse width is in the range of 1 to 1000 ns.

99. The method of claim 90, wherein a wavelength of the light is in the range between 250 and 400 nm.

100. The method of claim 90, wherein the acceptor substrate is only temperature stable up to at most 1400° C.

101. The method of claim 100, wherein the acceptor substrate is formed from silicon.

102. The method of claim 90, wherein, after carrying out the healing step, a step of introducing at least one further structural element of the semiconductor component into the composite substrate from the first surface and/or arranging at least one further structural element of the semiconductor component on the first surface is performed.
